(19) United States
(12) Patent Application Publication
(10) Pub. No.: US 2011/0221002 A1
(43) Pub. Date: Sep. 15, 2011

(54) MOS-TYPE ESD PROTECTION DEVICE IN SOI AND MANUFACTURING METHOD THEREOF

(75) Inventors: Jing Chen, Shanghai (CN); Jiexin Luo, Shanghai (CN); Qingqing Wu, Shanghai (CN); Bingxu Ning, Shanghai (CN); Zhongying Xue, Shanghai (CN); Xiaolu Huang, Shanghai (CN); Xi Wang, Shanghai (CN)

(73) Assignee: SHANGHAI INSTITUTE OF MICROSYSTEM AND INFORMATION TECHNOLOGY, CHINESE ACADEMY, Shanghai (CN)

(21) Appl. No.: 13/055,553

(22) PCT Filed: Jul. 14, 2010
(86) PCT No.: PCT/CN10/75160

§ 371 Date: Jan. 24, 2011

(30) Foreign Application Priority Data
Dec. 17, 2009 (CN) 200910201331.0

(51) Int. Cl. H01L 29/786; H01L 21/336

(52) U.S. Cl. 257/349; 438/151; 257/E29.276; 257/E21.411

(57) ABSTRACT

The present invention discloses a MOS ESD protection device for SOI technology and a manufacturing method for the device. The MOS ESD protection device comprises: an epitaxial silicon layer grown on top of an SOI substrate; a first side-wall spacer disposed on both sides of the epitaxial silicon layer so as to isolate the ESD protection device from the intrinsic active structures; a source region and a drain region disposed respectively on two sides of the epitaxial silicon layer; a poly silicon gate and a gate dielectric formed on top of the epitaxial silicon layer; and a second side-wall spacer disposed on both sides of the poly silicon gate of . ESD leakage current passes down to the SOI substrate for protection. Because ESD protection device and intrinsic MOS transistor are located in the same plane, this fabrication process can be inserted in the current MOS process flow.

### FIELD OF THE INVENTION

The present invention relates to the microelectronics and solid state electronics fields and more particularly to ESD protection device in SOI technology.

### BACKGROUND OF THE INVENTION

CMOS devices fabricated on silicon-on-insulator (SOI) substrate provide higher speed and consume less power. And electrostatic discharge (ESD) protection for higher device reliability has to be considered in circuit design and applications. The semiconductor IC industry usually adopts a resistive ESD circuitry, containing often diodes as input or output protection elements. In addition, to prevent breakdowns of internal components caused by extra current flowing into the internal circuit from ESD events, a MOS type ESD structure is usually arranged between the internal circuit and external input or output. But, ESD's failure mechanisms in SOI process are quite different from those in a bulk silicon CMOS process. Therefore, a buried oxide layer (BOX) is often applied to physically isolate the semiconductor devices. However, BOX significantly changes ESD's failure mode and protection mechanism.

MOS type ESD protection structure in SOI has been proposed. In the original structure, an ESD protection device and an intrinsic device are created in the same active region. The drawback of this original structure is that, in an ESD event, the leakage current can raise the electric potential of the intrinsic device in the active region, reinforce the floating body effect in the intrinsic SOI MOS device, and therefore impact the output characteristics of the intrinsic SOI MOS device. In an alternative structure, the ESD protection device and the intrinsic MOS device are separated by the shallow trench isolation (STI) process. The drawback of this structure is that, because of the isolation of BOX and STI, the ESD protection devices have low thermal dissipation capacity. In an ESD event, the ESD protection devices are easy to breakdown.

There are generally two techniques to fabricate an ESD protection device which has sufficient protection strength. One technique is to increase area of ESD protection components or to increase the total number of ESD protection components, resulting in undesired increase in chip area. The other technique is to remove part of the top silicon film and buried oxide layer on the SOI substrate, and create a special ESD protection structure on the exposed body region of the SOI substrate. However, exposing a body region of the SOI substrate will impact the consequent fabrication process.

There is a need for an effective ESD protection device which can be fabricated in a standard MOS process.

### SUMMARY OF THE INVENTION

Consistent with embodiments of the present invention, a MOS ESD protection structure in SOI is provided. In some embodiments, the MOS ESD protection structure includes an SOI substrate; an intrinsic active device and an ESD protection device formed over the SOI substrate side by side, the ESD protection device comprising: a trench formed in the SOI substrate; a first side-wall spacer disposed on the inside walls of the trench; an epitaxial silicon layer formed in the trench; a poly silicon gate formed on top of the epitaxial silicon; a gate dielectric disposed between the poly silicon gate and the epitaxial silicon layer; a source region and a drain region formed respectively on each side of gate; and a second side-wall spacer disposed on both sides of the poly silicon gate and the gate dielectric.

Preferably, the SOI substrate from bottom up comprises a body layer, a buried oxide layer and a top silicon film.

Preferably, the intrinsic active device is an intrinsic SOI MOS device, which comprises: a poly silicon gate formed on top of the SOI substrate; a gate dielectric disposed between the poly silicon gate of the SOI substrate; a source region and a drain region disposed respectively on each side of the poly silicon gate; a third side-wall spacer disposed on both sides of the poly silicon gate and the gate.

Preferably, the top silicon film in the intrinsic active device ends at the first side-wall spacer on one side, and ends at a shallow trench isolation wall on the other side.

Consistent with embodiments of the present invention, a method of manufacturing a MOS ESD is also provided. The method comprises steps of:
(A) providing a SOI substrate comprising three layers, the first layer is a body layer, the second layer is a buried oxide layer and a top silicon film; and providing a buffer layer on the SOI substrate;
(B) providing a silicon nitride layer on the buffer layer;
(C) forming a trench from the silicon nitride layer into the SOI substrate for an ESD protection cell to reside in;
(D) forming a first side-wall spacer on the inside walls of the trench to isolate the ESD protection cell region from intrinsic active structures;
(E) generating an epitaxial silicon layer in the ESD protection cell region;
(F) polishing the surface of the top silicon by the chemical mechanical polishing process;
(G) providing an ESD protection device comprising a poly silicon gate, a source region, and a drain on the epitaxial silicon layer.

Preferably, the method of forming a first side-wall spacer as follows: first, isotropic grow a layer of silicon dioxide based on step (C), and then anisotropic etch the silicon dioxide.

Preferably, the method of manufacturing a MOS ESD protection structure in SOI further comprises a step (H), which is creating a poly silicon gate, a source region and a drain region of an intrinsic SOI MOS device at the top silicon film, thereby the obtain ESD protection structure is MOS type.

The advantages of the present invention are listed as below. The ESD protection device connects to the body region of the SOI substrate directly, thereby the leakage current can down to the SOI substrate. Furthermore, the ESD protection device and the intrinsic MOS transistor in the active region are in the same plant via epitaxial process, in order to facilitate the follow-up process.

### BRIEF DESCRIPTION OF THE DRAWINGS

FIG. 1 is a cross sectional view of an SOI substrate.

FIG. 2 is a cross sectional view of an ESD stack including a silicon dioxide buffer layer and a silicon nitride barrier layer grown on the SOI substrate according to one embodiment of the present invention.

FIG. 3 is a cross sectional view of an ESD protection cell region and a silicon dioxide spacer fabricated in the ESD stack according to one embodiment of the present invention.

FIG. 4 is a cross sectional view of an ESD protechion cell region which is epitaxially grown in the ESD stack of the SOI substrate according to one embodiment of the present invention.

FIG. 5 is a cross sectional view of an exemplary ESD protection device and an intrinsic SOI MOS structure according to one embodiment of the present invention.

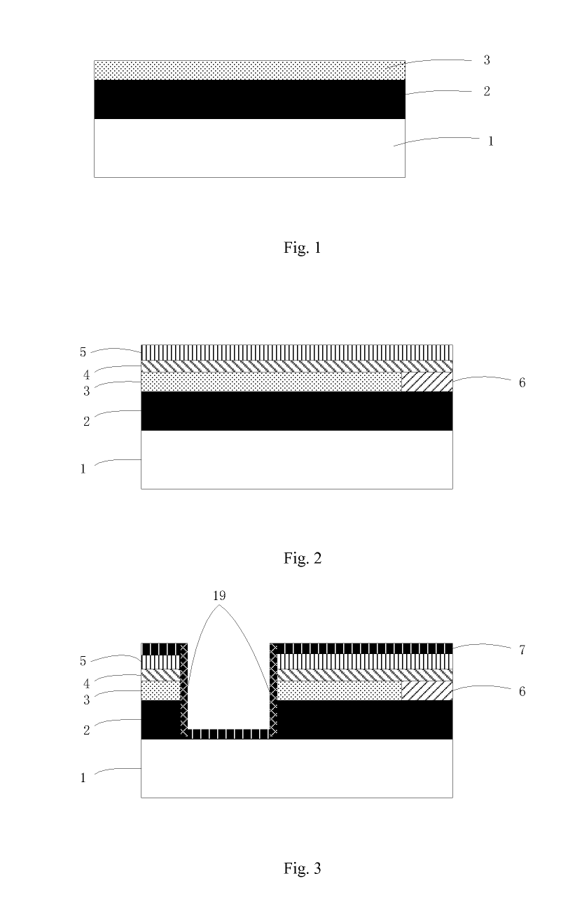

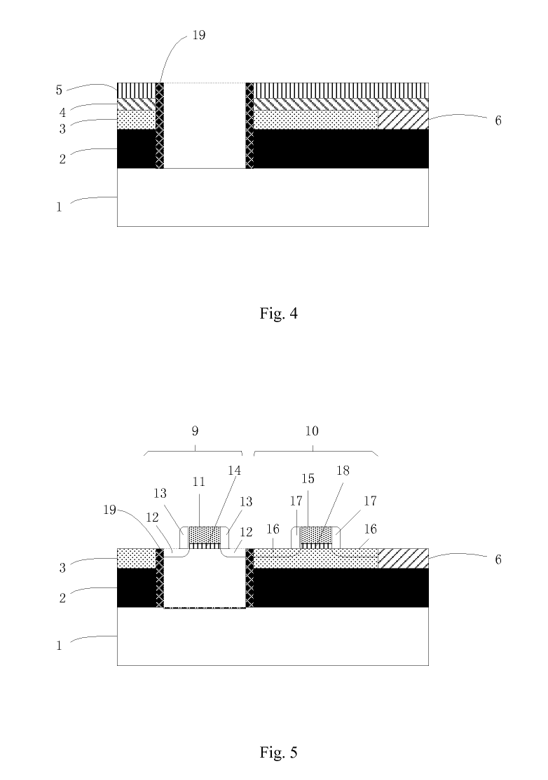

TABLE 1
Summary of reference numbers in FIGS. 1-5

| | |
|---|---|
| 1 body region of the SOI substrate | 2 buried oxide layer of the SOI substrate |
| 3 top silicon film | 4 silicon dioxide buffer layer |
| 5 silicon nitride barrier layer | 6 shallow trench isolation wall |
| 7 silicon dioxide by isotropic growing | 8 epitaxial silicon layer |
| 9 ESD protection device | 10 intrinsic SOI MOS structure |
| 11 poly silicon gate of the ESD | 12 source region and drain region of the |
| protection device | ESD protection device |
| 13 second side-wall spacer of the ESD | 14 silicon dioxide gate dielectric of the |
| protection device | ESD protection device |
| 15 poly silicon of the intrinsic SOI | 16 source region and drain region of the |
| MOS structure | intrinsic SOI MOS structure |
| 17 third side-wall spacer of the | 18 silicon dioxide gate dielectric of the |
| intrinsic SOI MOS structure | intrinsic SOI MOS structure |
| 19 first side-wall spacer | |

### DETAILED DESCRIPTION OF THE INVENTION

The present invention is further explained in detail according to the accompanying drawings.

### First Embodiment

FIG. 5 illustrates the cross section of a MOS type ESD protection structure fabricated in an SOI stack consistent with the first embodiment of the present invention. The protection structure includes an ESD protection device 9 which comprises an epitaxial silicon layer 8 contacting directly a body region 1 of an SOI substrate; a first side-wall spacer 19 disposed vertically on both sides of the epitaxial silicon layer 8 so as to isolate the ESD protection device 9 from the intrinsic active structure 10; a poly silicon gate 11 of the ESD protection device 9 formed on top of the epitaxial silicon layer 8; a gate dielectric 14 disposed between the poly silicon gate 11 and the epitaxial silicon layer 8; a source region and a drain region formed in the epitaxial silicon layer 8 on left and right ends of the gate 11; and a second side-wall spacer 13 disposed on both sides of the poly silicon gate 11. The gate dielectric 14 is formed of materials, for example, silicon dioxide.

The ESD protection structure is built on a SOI substrate, and the SOI substrate from bottom up includes a body region 1, a buried oxide layer 2 and a top silicon film 3. The ESD protection structure further include an intrinsic SOI MOS device 10, which is isolated from the ESD protection device 9 by the first side-wall spacer 19. The intrinsic SOI MOS device 10 has a poly silicon gate 15 formed on the central location over the silicon film 3; a gate dielectric 18 disposed between the poly silicon gate 15 and the top silicon film 3; a source region and a drain region 16 disposed in the top silicon film 3 and respectively at the left and right side of gate 15; a third side-wall spacer 17 disposed on both sides of the poly silicon gate 15 and gate dielectric layer 18. The gate dielectric layer 18 is formed of materials, for example, silicon dioxide. The top silicon film 3 in the intrinsic SOI MOS structure 10 is located next to a first side-wall spacer 19 on one side, and connects to a shallow trench isolation wall 6 on the other side.

Referring to FIGS. 1 through 5, an exemplary method of fabricating a MOS ESD protection structure in SOI includes the following steps.

(A) A stack of SOI substrate is provided, including a SOI body film 1, a buried oxide layer 2 and a top silicon film 3 from bottom up, and a silicon oxide buffer layer 4 on the SOI substrate. A number of thin film growing techniques may be applied in forming the oxide films, for example, thermal oxidation, diffusion, RTP, PVD, CVD, MBE, etc.

(B) A silicon nitride layer 5 is formed on the silicon dioxide buffer 4 to complete a full-film stack.

(C) An opening in the full-film stack as an ESD protection cell region 9 is formed by a lithography process, and the ESD protection cell region 9 extends from the silicon nitride layer 5 into the bottom of the buried oxide layer 2.

(D) A first side-wall spacer 19 is deposited in the opening in step (C) to provide isolation between the ESD protection cell region 9 and the intrinsic active structure 10.

(E) Grow an epitaxial silicon layer 8 is grown selectively in the ESD protection cell region by a film growing process, for example, CVD, PVD, RTP, etc.;

(F) The full-film stack is polished down to the top silicon film 3 by a polishing process, for example, the CMP (chemical-mechanical polishing).

(G) A poly silicon gate 11, gate dielectric layer 12, a source region and a drain region 19 are formed over the epitaxial silicon layer 8.

The method of forming a first side-wall spacer is explained as follows: after an opening in the full-film is made in step (C), a layer of silicon dioxide is uniformly deposited inside the opening and the top surface containing the silicon dioxide and nitride is removed, by applying, for example, an anisotropic etch process, a polish process, etc.

The method of manufacturing a MOS ESD protection structure in SOI further comprises another step (H), which creates an intrinsic SOI MOS device at the top silicon film, containing a poly silicon gate, a source region and a drain region of.

In the present embodiment, the ESD protection device connects to the body region of the SOI substrate directly, thereby the leakage current can exit down to the SOI substrate. Moreover, the ESD protection device and the intrinsic MOS transistor in the active region are in the same plant via epitaxial process. As a result, the ESD device fabrication can easily be integrated with the existing IC process.

### Second Embodiment

A method of manufacturing a MOS ESD protection structure in SOI is provided in the second embodiment of the present invention, which is disclosed as follows:

First, a silicon oxide buffer layer is grown on the top surface of the SOI substrate by thermal oxidation. The silicon oxide buffer helps with relieving the tensile stress between the top silicon film and a silicon nitride layer by the following process.

Second, a silicon nitride layer is deposited on the silicon dioxide buffer. The nitride layer protects the top silicon film from oxidation in the following process.

Third, a trench is opened up by a lithography process in the stack of film prepared in the first and second steps. The opening forms a region for fabricating an ESD protection cell.

Next, a first side-wall spacer is formed over the inside walls of the trench opening. The spacer isolates the ESD protection cell region from the intrinsic active structures. The method of forming the first side-wall spacer includes the following: First, grow an even layer of silicon dioxide inside the trench, and then etch the silicon dioxide layer anisotropically. Then grow an epitaxial silicon layer selectively inside the trench opening by a deposition technique, such as the chemical vapor deposition, plasma vapor deposition, and rapid thermal process, etc. The epitaxial silicon and the substrate silicon share similar crystalline silicon properties. And, Chemical-Mechanical Polishing process (CMP) is applied to smooth the surface of the top silicon film. Thus, the MOS type ESD protection cell and the intrinsic MOS devices are separated. The ESD protection device electrically connects to the body region of the substrate directly, thereby, in an ESD event, the leakage current reaches down to the SOI substrate, and therefore the breakdown of the MOS type ESD protection cell by the heat of current can be avoided.

Finally, create an SOI MOS type ESD protection device, including a gate, gate dielectric, a source and a drain, on the epitaxial silicon layer, and create an intrinsic SOI MOS type transistor on the top silicon film.

The present invention relates to field effect transistor (MOS) type electrostatic discharge (ESD) protection structure in a silicon-on-insulator (SOI) substrate and its manufacturing method for the same. The method includes creating a MOS type ESD protection device on a semiconductor supporting substrate, located between an internal circuit and an input or output protection components. The ESD protection device protects the circuit from breakdowns of the internal components from excess current of external ESD events entering into internal circuit. This structure can prevent the ESD leakage current damaging components, and ensure the leakage current reaching the substrate body region in an ESD event. Otherwise the current will raise the active region potential and lead to ESD protection components easy breakdown, and then influence the intrinsic device performance. The manufacturing method is compatible with the SOI CMOS process, and will not damage the following process.

The above description of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

1. A MOS ESD protection structure in SOI, comprising:
an SOI substrate;
an intrinsic active device and an ESD protection device formed over the SOI substrate side by side;
the ESD protection device comprising:
a trench formed in the SOI substrate;
a first side-wall spacer disposed on the inside walls of the trench;
an epitaxial silicon layer formed in the trench;
a poly silicon gate formed on top of the epitaxial silicon;
a gate dielectric disposed between the poly silicon gate and the epitaxial silicon layer;
a source region and a drain region formed respectively on each side of gate; and
a second side-wall spacer disposed on both sides of the poly silicon gate and the gate dielectric.

2. The MOS ESD protection structure in SOI of claim 1, wherein the SOI substrate comprises a body layer, a buried oxide layer and a top silicon film.

3. The MOS ESD protection structure in SOI of claim 1, wherein the intrinsic active device comprises:
a poly silicon gate formed on top of the SOI substrate;
a gate dielectric disposed between the poly silicon gate of the SOI substrate;
a source region and a drain region disposed respectively on each side of the poly silicon gate;
a third side-wall spacer disposed on both sides of the poly silicon gate and the gate.

4. The MOS ESD protection structure in SOI of claim 3, wherein the top silicon film in the intrinsic active device ends at the first side-wall spacer on one side, and ends at a shallow trench isolation wall on the other side.

5. The MOS ESD protection structure in SOI of claim 1, wherein the intrinsic active device is an intrinsic SOI MOS device.

6. A method of manufacturing a MOS ESD protection structure in SOI comprises steps of:
(A) providing a SOI substrate comprising three layers, the first layer is a body layer, the second layer is a buried oxide layer and a top silicon film; and providing a buffer layer on the SOI substrate;
(B) providing a silicon nitride layer on the buffer layer;
(C) forming a trench from the silicon nitride layer into the SOI substrate for an ESD protection cell to reside in;
(D) forming a first side-wall spacer on the inside walls of the trench to isolate the ESD protection cell region from intrinsic active structures;
(E) generating an epitaxial silicon layer in the ESD protection cell region;
(F) polishing the surface of the top silicon by the Chemical-Mechanical Polishing process;
(G) providing an ESD protection device comprising a poly silicon gate, a source region, and a drain on the epitaxial silicon layer.

7. The method of manufacturing a MOS ESD protection structure in SOI of claim 6, wherein forming a first side-wall spacer as follows: isotropic grow a layer of silicon dioxide based on step (C) first, and then anisotropic etch the silicon dioxide.

8. The method of manufacturing a MOS ESD protection structure in SOI of claim 6, further comprises a step (H), which is creating a poly silicon gate, a source region and a drain region of an intrinsic SOI MOS device at the top silicon film, thereby the obtain ESD protection structure is MOS type.

9. The method of manufacturing a MOS ESD protection structure in SOI of claim 6, the buffer layer is a thermally grown silicon dioxide layer.

10. The method of manufacturing a MOS ESD protection structure in SOI of claim 6, wherein the epitaxial silicon layer is generated from one or more of the processes comprising CVD, PVD, ALD (atomic layer deposition), MBE, and a rapid thermal process.

11. The method of manufacturing a MOS ESD protection structure in SOI of claim 6, wherein polishing the top film comprises a chemical-mechanical polishing process.
